(19) United States
(12) Patent Application Publication
(10) Pub. No.: US 2013/0082177 A1
(43) Pub. Date: Apr. 4, 2013

(54) CIRCUIT PATTERN INSPECTION APPARATUS AND CIRCUIT PATTERN INSPECTION METHOD

(71) Applicants: Takashi Hiroi, Yokohama (JP); Mari Nozoe, Hino (JP); Takuma Yamamoto, Mito (JP); Masaaki Nojiri, Hitachinaka (JP); Mitsuru Okamura, Mito (JP)

(72) Inventors: Takashi Hiroi, Yokohama (JP); Mari Nozoe, Hino (JP); Takuma Yamamoto, Mito (JP); Masaaki Nojiri, Hitachinaka (JP); Mitsuru Okamura, Mito (JP)

(73) Assignee: HITACHI HIGH-TECHNOLOGIES CORPORATION, Tokyo (JP)

(21) Appl. No.: 13/702,923

(22) PCT Filed: May 13, 2011
(86) PCT No.: PCT/JP2011/002659

§ 371 Date: Dec. 7, 2012

(30) Foreign Application Priority Data
Jun. 7, 2010 (JP) 2010-129523

(51) Int. Cl. H01J 37/28; H01J 37/20

(52) U.S. Cl. CPC H01J 37/28; H01J 37/20
USPC 250/310; 250/442.11

(57) ABSTRACT

High-speed inspection is performed with appropriate sensitivity according to the pattern density and pattern characteristic of a device.

The pixel dimension used in image acquisition is changed in accordance with the pattern density of a device. An image is acquired at high speed by changing the beam scan speed and the stage drive speed in accordance with the pixel dimension and eliminating an error by controlling the amount of beam delay. The acquired image is so resampled that the image dimensions of the acquired image and a reference image are equally sized, and the acquired image and the reference image are then aligned with each other. The aligned images are resampled in accordance with a preset pixel dimension to extract a difference between the images with the sensitivity according to the pixel dimension.

### TECHNICAL FIELD

The present invention relates to a technology of an inspection apparatus that captures an image of a variety of samples, such as a semiconductor device, a liquid crystal device, and any other substrate device having a circuit pattern; a chip cut off a substrate and any other semiconductor device; and a liquid crystal substrate, by using an electron beam, an ion beam, or any other charged particle beam and processes the image to detect a portion having a pattern different from a normal pattern as a defect. The invention also relates to a technology of an inspection method used with the inspection apparatus.

### BACKGROUND ART

Each of the samples described above is formed by using a film formation technology to which a semiconductor processing technology is applied to layer circuit patterns on a substrate, such as a semiconductor substrate and a glass substrate. To detect a defect produced in each of the layers, an inspection apparatus based on a charged particle beam, such as an electron-beam-based inspection apparatus and observation apparatus, has been used.

An electron-beam-based inspection apparatus compares a secondary charged particle image of a pattern, such as a secondary electron image or a reflected electron image obtained by irradiating a sample under inspection with an electron beam, with a reference image believed to have the same pattern and identifies a location where the difference between the two images is large as a defect. An on-wafer distribution of the detected defects is statistically analyzed or the shape and other characteristics of the detected defects are closely analyzed, whereby a problem with the manufacture of the wafer having the defects can be analyzed.

The electron-beam-based inspection apparatus and observation apparatus described above are required to not only perform inspection at high speed (throughput) but also detect a minute defect with high sensitivity, that is, capture an image with resolution high enough to detect a minute defect. The inspection speed and the high-resolution imaging are not generally achieved at the same time, which is what is called a tradeoff. That is, acquiring an inspection image having a small pixel size in order to detect a minute defect prolongs a period required to capture an image or perform image processing for defect detection and hence lowers the throughput. On the other hand, increasing the pixel size in order to improve the throughput degrades the performance in detection of a defect smaller than the pixel size. A variety of technologies have been developed to achieve both the inspection throughput and the inspection sensitivity within the tradeoff restriction described above.

For example, Patent Literature 1 discloses an invention that focuses on the fact that the amount of positional shift of defects depends on directions and enlarges the field of view (FOV) of an image in the direction in which the positional precision is poor, that is, enlarges the field of view anisotropically by increasing the number of pixels in the X or Y direction in which the positional precision is poorer. According to the invention described in Patent Literature 1, it is unnecessary to enlarge the FOV in the direction in which the positional precision is superior, whereby the region across which the electron beam is scanned will not increase with the pixel size maintained at a small value as compared with a case where the FOV is enlarged isotropically, and hence the throughput will not decrease.

Patent Literature 2 discloses an electron-beam-based inspection apparatus capable of choosing between two inspection modes, a speed priority mode and an inspection sensitive priority mode, and changing the pixel size in accordance with the choice a user of the apparatus has made. In the inspection sensitive priority mode, a pixel size smaller than that in the speed priority mode is chosen, whereas in the speed priority mode, a larger pixel size is chosen.

When a semiconductor wafer is considered as an object to be inspected, circuit patterns repeated at different cycles (pitches) are formed in different areas of the wafer in some cases. In view of the circumstance described above, Patent Literature 3 discloses an electron-beam-based inspection apparatus capable of specifying different regions A and B at the time of inspection region setting, inputting a comparison pitch and a comparison direction in each of the areas A and B into an inspection file, and changing the comparison pitch and the comparison direction during a set of series of inspection operation during which the electron beam is scanned over the semiconductor wafer.

### CITATION LIST

### Patent Literature

PTL 1: JP-A-2007-101202 (U.S. Pat. No. 7,554,082)

PTL 2: JP-A-2009-194249 (United States Patent Application Publication No. 2009/208092)

PTL 3: JP-A-2006-216611 (United States Patent Application Publication No. 2006/0171593)

### SUMMARY OF INVENTION

### Technical Problem

A sample to be inspected by an inspection apparatus, for example, a circuit pattern formed on a semiconductor wafer, has different pattern densities in different regions. For example, a logic wafer has the following circuit regions having different pattern densities: a high-density memory region where memory cell patterns are formed; a middle-density basic region, such as a direct peripheral circuit and a logic circuit; a low-pattern-density I/O region, such as an I/O circuit; and a region not to be inspected where no pattern is present or a dummy pattern or any other pattern formed for the convenience of light-exposure operation is present. The term “pattern density” used herein means how much a specific circuit pattern occupies a certain region in a chip and is an index representing how the pattern is fine. When the distance between patterns in a region under inspection (distance between wiring lines or pitch between hole patterns, for example) is small, the pattern density is high. In a region where the distance between patterns is small, each of the formed patterns is also fine or small in size (width of wiring pattern or diameter of contact hole or via hole, for example) in many cases. The pattern density may be replaced with other density indices, such as the narrowest line width of a pattern, the smallest diameter of a hole provided in a pattern, and the shortest distance between holes.

Since any minute defect is critical in the high-density memory region, high-sensitivity inspection is required. In the middle-density basic region and the low-density I/O region, a defect having a dimension according to the pattern density therein needs to be detected. In a region where no pattern or a dummy pattern is present, a defect of some degree in size will not be critical. Rather, the two regions described above possibly have a large number of abnormalities that do not affect circuit characteristics and should not undergo defect detection.

It is therefore desired to provide a high-speed inspection method and apparatus that perform inspection with appropriate sensitivity according to the pattern density and pattern characteristic of a region under inspection.

An electron-beam-based inspection apparatus and observation apparatus of related art performs inspection with the pixel size fixed irrespective of the type of a region of an object under inspection. That is, images of a high-density memory region and a low-density I/O region are captured at the same resolution, which means that an image of a region where no high-sensitivity inspection is required is captured at the same resolution as that used to capture an image of a region that requires high-sensitivity inspection, resulting in a decrease in inspection throughput.

### Solution to Problem

The invention solves the problem with related art by acquiring an image of a region of an object under inspection with an appropriate pixel size changed in accordance therewith. More specifically, the problem is solved by acquiring an image of a sample under inspection with the pixel size changed according to the pattern density of the sample in a single inspection sequence in which a single sample is inspected. A specific method for changing the pixel size will be described in detail in the sections where embodiments are described. The invention is applicable not only to an electron-beam-based inspection apparatus and observation apparatus but also to an optical inspection apparatus.

### Advantageous Effects of Invention

According to the invention, a high-speed inspection method and apparatus having appropriate sensitivity according to the pattern density and pattern characteristic of a device are provided. Since inspection is performed with the pixel dimension changed in accordance with the pattern density and characteristic, the period required for image acquisition and inspection can be greatly shortened as compared with inspection methods of related art. As a result, a high-speed inspection method and apparatus having appropriate sensitivity according to the pattern density and pattern characteristic of a device are provided.

### BRIEF DESCRIPTION OF DRAWINGS

FIG. 1 is a descriptive diagram of a variable pixel dimension that describes a solution to the problem of related art.

FIG. 2 is an overall configuration diagram in a first embodiment according to the invention.

FIG. 3 describes an inspection method in the first embodiment according to the invention.

FIG. 4 describes pattern density information conversion in the first embodiment according to the invention.

FIG. 5 describes a variable pixel dimension setting dialog in the first embodiment according to the invention.

FIG. 6 describes a pixel dimension setting method in the first embodiment according to the invention.

FIG. 7 describes abeam scan method in the first embodiment according to the invention.

FIG. 8 describes a stage drive method in the first embodiment according to the invention.

FIG. 9 describes the amount of beam delay in the first embodiment according to the invention.

FIG. 10 is an overall configuration diagram of a defect identification method in the first embodiment according to the invention.

FIG. 11 describes resampling for alignment in the first embodiment according to the invention.

FIG. 12 describes resampling for difference image extraction in the first embodiment according to the invention.

FIG. 13 shows a target pattern layout in a second embodiment according to the invention.

FIG. 14 describes a stage drive method in the second embodiment according to the invention.

FIG. 15 is an overall configuration diagram in a third embodiment according to the invention.

FIG. 16 describes pixel dimensions in a fourth embodiment according to the invention.

### DESCRIPTION OF EMBODIMENTS

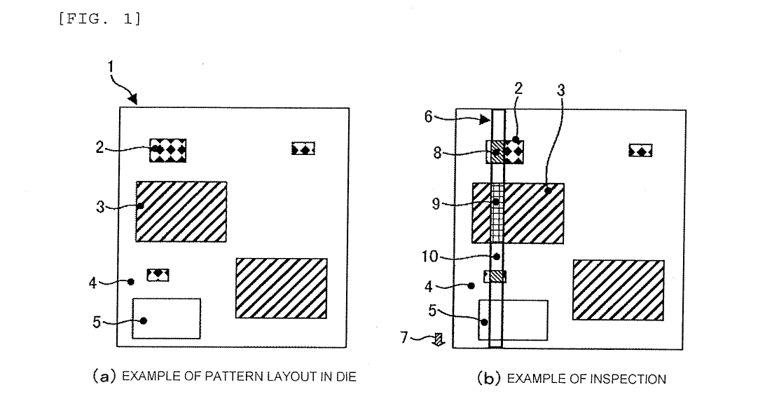

A basic concept of the invention will first be described with reference to FIG. 1.

FIG. 1(a) is a descriptive diagram showing an example of a pattern layout inside a die that forms a logic wafer, and FIG. 1(b) is a descriptive diagram showing an example of inspection of the pattern. In the case of a logic wafer, the pattern of a die 1 is formed of a high-density region 2 including memory cells and other similar components, a middle-density region 3 including a logic circuit and other similar components, a low-density region 4 including an I/O circuit and other similar components, and a region not to be inspected 5 having a dummy pattern and other patterns. The arrow labeled with reference numeral 7 represents movement of a stage on which the logic wafer is placed and shows the direction in which the stage moves. To inspect the die having the layout described above, for example, a stripe region to be inspected is sequentially set from the left end of the die, and the entire die is then inspected. The term “stripe” used herein means continuous image data formed from an image signal provided by continuously moving an object under inspection in one direction and scanning an electron beam or an optical beam, such as a laser beam, in a direction that intersects the continuously moving sample. At the time of setting an inspection recipe before actual inspection, an inspection region is set by virtually disposing a stripe on the object under inspection.

Consider now that inspection is performed by setting a scan stripe 6 and acquiring an image of the scan stripe 6 in synchronization with the stage movement 7. The image is acquired by dynamically changing the pixel dimension in accordance with the pattern density as follows: The high-density region 2 undergoes minute-pixel image acquisition 8; the middle-density region 3 undergoes small-pixel image acquisition 9; and the low-density region 4 and the region not to be inspected 5 undergo large-pixel image acquisition 10. The terms “density region” and “pattern density region” are synonymous with each other. The acquired image undergoes inspection with appropriate inspection sensitivity set in accordance with each of the regions. In this process, the region not to be inspected 5 does not undergo defect detection. As a result, the high-density region 2, a minute-pixel image of which is acquired, undergoes high-sensitivity inspection for detecting minute defects, and the middle-density region 3, which is inspected based on a small-pixel dimension, undergoes inspection that detects defects having dimensions according to the small pixel dimension. On the other hand, the low-density region 4, where no image thereof is acquired by using unnecessarily minute pixels, undergoes inspection that detects defects having dimensions that need to be detected. In the region not to be inspected 5, no unnecessary defect detection is carried out.

The inspection method using a variable pixel dimension according to the pattern density and characteristic allows the period required for image acquisition and inspection to be greatly shortened as compared with a method of related art in which the entire scan stripe 6 is inspected under the conditions according to which an image of the high-density region is acquired. A high-speed inspection method or inspection apparatus having appropriate sensitivity according to the pattern density and pattern characteristic of a device are thus provided.

### First Embodiment

A first embodiment will be described below in detail with reference to the drawings.

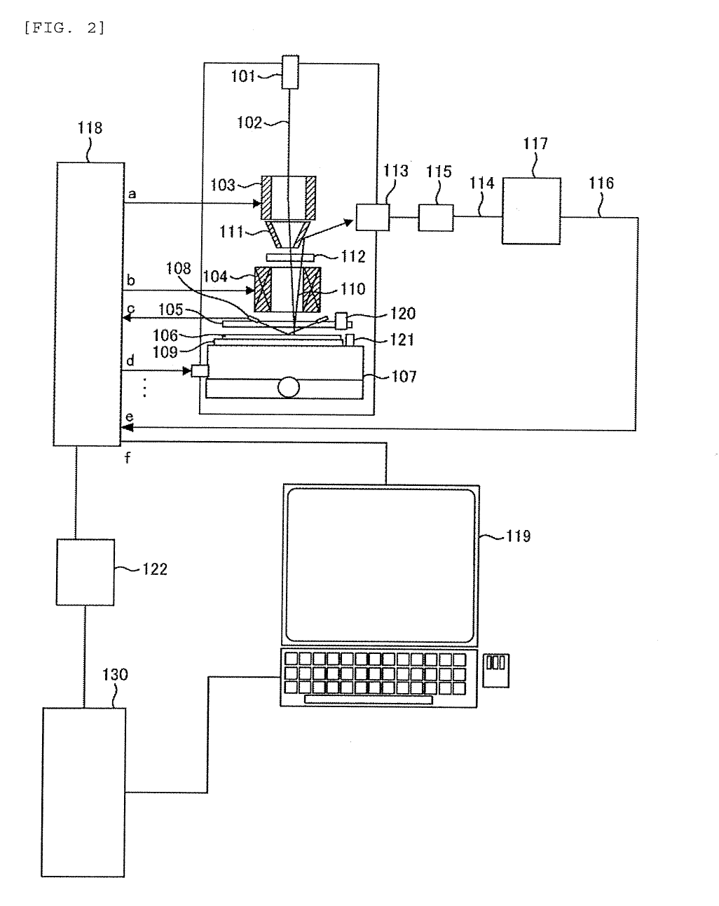

FIG. 2 is a longitudinal cross-sectional view showing the configuration of an inspection apparatus according to the present embodiment. The inspection apparatus according to the present embodiment is a variation of a scanning electron microscope, and a key portion of the apparatus is accommodated in a vacuum chamber. The reason for this is to irradiate a semiconductor wafer or any other substrate with a primary charged particle beam. The inspection apparatus according to the present embodiment is formed, for example, of a charged particle column in which a primary charged particle beam 102 emitted from an electron source 101 irradiates a wafer 106 placed on a sample table 109 and a detector 113 detects resultant secondary charged particles 110, such as secondary electrons or reflected electrons, and outputs the detected particles as a secondary charged particle signal; an XY stage 107 that moves the sample table 109 in the XY plane; a defect identification unit 117 that converts the secondary charged particle signal outputted from the column into an image, compares the image with a reference image, and extracts a pixel showing a difference between the two image signals as a defect candidate; and an overall controller 118 that oversees and controls the charged particle column, the XY stage 107, and the defect identification unit 117 described above. The XY stage 107 and the sample table 109 are held in the vacuum sample chamber.

To concentrate the energy of the primary charged particle beam 102 on the wafer 106, the primary charged particle beam 102 is focused by an objective lens 104 to a narrow beam. As a result, the diameter of the primary charged particle beam 102 is very small on the wafer 106. The primary charged particle beam 102 is deflected by a deflector 103, directed to a predetermined region on the wafer 106, and scanned over the wafer 106. A two-dimensional image can be formed by synchronizing the scanning position that moves with the timing at which the secondary charged particles (secondary signal) 110 are detected by the detector 113.

A circuit pattern formed on the surface of the wafer 106 is made of a variety of materials, some of which may cause a charging phenomenon in which charge is accumulated due to the irradiation of the primary charged particle beam 102. Since the charging phenomenon disadvantageously changes the brightness of an image and deflects the trajectory of the primary charged particle beam 102 incident on the wafer 106, a charging control electrode 105 is provided in a position upstream of the wafer 106 to control the intensity of the electric field.

Before the wafer 106 is inspected, an image of a standard sample piece 121 is captured by irradiating it with the primary charged particle beam 102. Based on the captured image, the irradiated position coordinates of the primary charged particle beam and the focus thereof are calibrated. As described above, since the diameter of the primary charged particle beam 102 is very small, and the width over which the scanning is performed by the deflector 103 is much smaller than the size of the wafer 106, an image formed by the primary charged particle beam 102 is very small. In view of the fact described above, before the inspection starts but after the wafer 106 is placed on the XY stage 107, a relatively low magnification image captured with an optical microscope 120 is used to detect a coordinate calibration alignment mark provided on the wafer 106, and the XY stage 107 is so moved that the alignment mark is positioned below the primary charged particle beam 102 for the coordinate calibration.

Focus calibration is performed as follows: A Z sensor 108 that measures the height of the wafer 106 is used to measure the height of the standard sample piece 121 and then the height of the alignment mark provided on the wafer 106; and the measured values are used to adjust the magnitude at which the objective lens 104 is energized in such a way that the alignment mark is present within the focus range of the primary charged particle beam 102 focused by the objective lens 104.

To maximize the detection of the secondary signal 110 produced by the wafer 106, a secondary signal deflector 112 deflects the secondary signal 110 in such a way that a large portion thereof impinges on a reflector 111, and the detector 113 detects second secondary electrons reflected off at the reflector 111.

The overall controller 118 controls, for example, the coordinate and focus calibration described above. The overall controller 118 further sends a control signal “a” to the deflector 103 and a control signal “b” carrying exciting current magnitude to the objective lens. The overall controller 118 further receives a measured value “c” sent from the Z sensor 108 and representing the height of the wafer 106 and sends the XY stage 107 a control signal “d” for controlling the XY stage 107.

The signal detected by the detector 113 is converted by an A/D converter 115 into a digital signal 114.

The defect identification unit 117 produces an image from the digital signal 114, compares the image with the reference image, extracts a plurality of pixels having brightness values different from those of the reference image as defect candidates, and sends the overall controller 118 a defect information signal “e” containing an image signal of the defects candidates and corresponding coordinates on the wafer 106.

The inspection apparatus according to the present embodiment further includes a console 119, which is connected to the overall controller 118. An image of the defects is displayed on a screen of the console 119, and the overall controller 118 computes the control signal “a” for controlling the deflector 108, the control signal “b” representing the magnitude according to which the objective lens is controlled, the control signal “d” for controlling the XY stage 107 based on inspection conditions f inputted through the console 119. The console 119 includes a keyboard and a pointing device (such as mouse) with which the inspection conditions described above are inputted, and the user of the apparatus operates the keyboard and the pointing device to input the inspection conditions described above through a GUI window displayed on the screen.

The inspection apparatus according to the present embodiment further includes a pattern density information computing processor 122, which has a function of producing information on the density of a pattern in a step to be inspected based on design information when an operator issues an instruction through the console 119. The density information computing processor 122 can operate independently of the inspection operation or in parallel thereto even during the inspection operation. Further, the inspection apparatus according to the present embodiment is connected over a network to a design data server (CAD server) 130 that stores design data on a semiconductor circuit pattern that is a sample to be inspected and can acquire the design data from the CAD server 130 as required. The design data is stored, for example, in a GDS format. To this end, the density information computing processor 122 includes a memory or secondary storage means (such as hard disk drive) into which the design data is read as well as a computing element for computing pattern density information.

The density information computing processor 122 in the present embodiment has a function of setting a region to be inspected based on the design data on a semiconductor circuit pattern. Before inspection starts, the thus configured density information computing processor 122 extracts pattern information from the design information in response to an operator's instruction through the console 119, which is called density information generation. Further, a recipe for determining inspection conditions and an inspection procedure is created before the inspection.

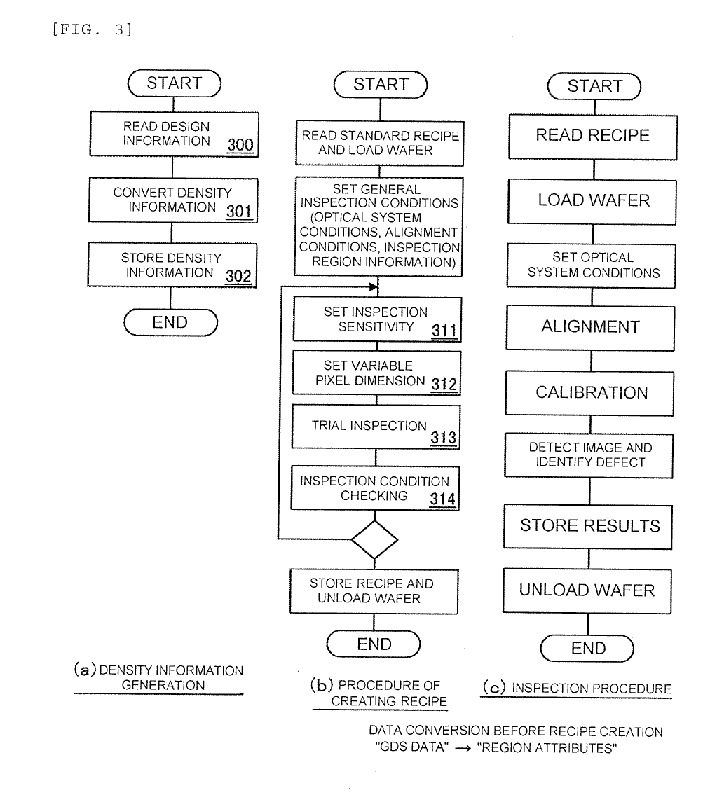

FIGS. 3(a), 3(b), and 3(c) are a flowchart showing the density information generation, a flowchart showing the recipe creation, and a flowchart showing the procedure of a main inspection performed in accordance with the thus created recipe, respectively.

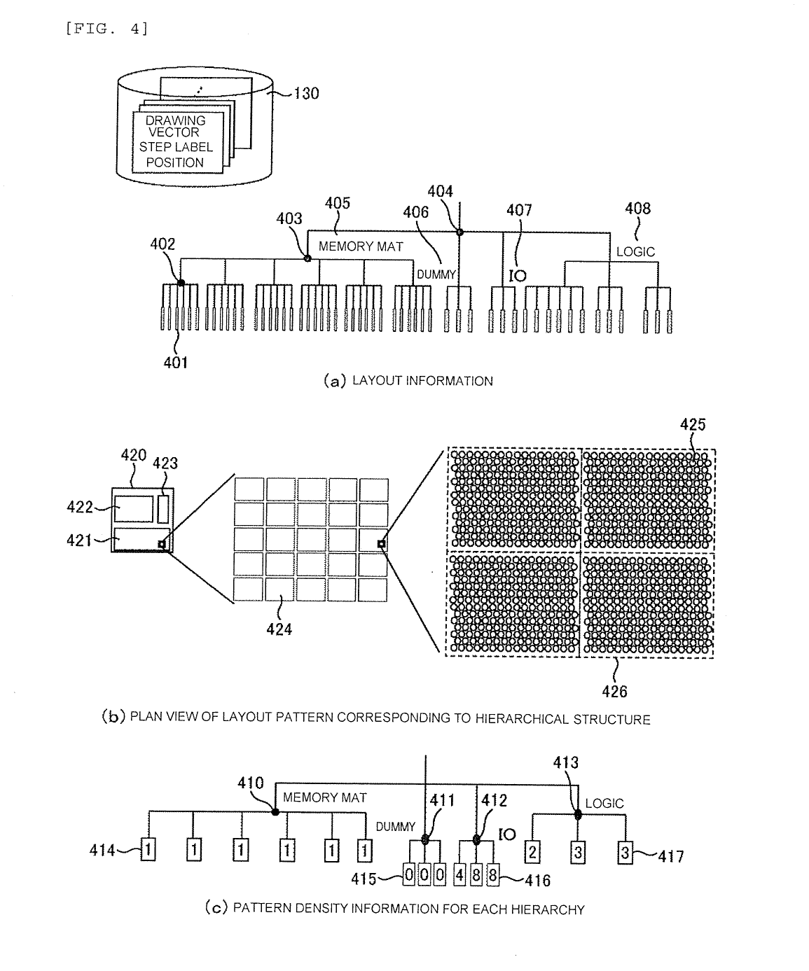

First, in step 300 in FIG. 3(a), the density information computing processor 122 reads design information on a wiring pattern on a sample under inspection. It is assumed that the reading action starts in response to an operation of the operator of the apparatus or a certain instruction therefrom. It is further assumed that the design information is provided in a GDS2 format. A description will be made of conversion of design information into density information performed in density information conversion step 301 with reference to FIGS. 4(a) and 4(b).

FIG. 4(a) is a schematic view showing the logical configuration of the design information to be read, and FIG. 4(b) is a schematic view showing the configuration of the pattern density information corresponding to the pattern layout information shown in FIG. 4(a). As well known, a semiconductor device is formed by stacking a plurality of circuit pattern layers on a semiconductor substrate. The design information shown in FIGS. 4(a) and 4(b) corresponds to information on the design of an entire single layer of the plurality of layers.

A plurality of chips having the same circuit pattern are arranged on the semiconductor wafer. The layout in each of the chips is divided into a plurality of regions, such as a memory region, a peripheral circuit region, and an I/O region, and each of the regions is further divided into smaller regions. For example, the memory region can be divided into memory mats, memory cells, and other smaller constituent units and eventually to minimum constituent units that form the circuit pattern, such as a gate electrode of a transistor and a wiring line that form a memory cell (every drawn pattern printed on wafer in lithography process). The layout information can therefore be expressed by a hierarchical structure shown in FIG. 4(a).

Drawing data 401, which are the minimum constituent units described above, are located at the lowest level of the hierarchical structure, and a plurality of the drawing data 401 together form a higher-level constituent unit of the circuit pattern. A branch in the hierarchical structure therefore represents a higher-level constituent unit formed of a plurality of lower-level structural units. In the following description, a constituent unit corresponding to a detail below a branch in the hierarchical structure is referred to as a “part.” For example, in the hierarchical structure shown in FIG. 4(a), a plurality of drawing data together form a part 402 in a first hierarchy. A plurality of parts 402 together form a part 403 in a second hierarchy. A plurality of parts 403 together form information 404 on design of the entire layer. Although the design information 404 in FIG. 4(a) is formed of three hierarchies for ease of description, the hierarchical structure of an actual circuit pattern is much more complex.

FIG. 4(b) shows an example of a layout pattern represented by the hierarchical structure shown in FIG. 4(a). A left-end portion of FIG. 4(b) shows an in-chip layout, and a memory region 421, a logic region 422, an I/O region 423, and other regions are formed in a chip 420. The memory region 421 is formed of a plurality of memory mats 424 shown in a right-side portion. A right-end portion of FIG. 4(b) is an enlarged view of part of one of the memory mats 424, each of which is formed of a large number of memory cells 425.

In the relationship between FIGS. 4(a) and 4(b), for example, the part 403, “memory mat,” corresponds to the memory mat 424 in FIG. 4(b), and the drawing data 401 in the lowest hierarchy correspond to the memory cells 425. A region 426 formed of a large number of memory cells 425 corresponds to the part 402.

The part in each of the hierarchies is given apart label bearing a part name. For example, (constituent unit corresponding to) the hierarchy that contains the part 403 is given a part label 405, “memory mat.” A part label 406, “dummy,” a part label 407, “I/O,” and a part label 408, “logic” are those given to constituent units corresponding to specific hierarchies. A part label is given to the constituent unit in every hierarchy in some cases or only to a functionally significant constituent unit (functional module; memory mat, for example) in other cases. The part labels shown in FIG. 4(a) bear intuitively understandable names, but part labels given in actual design information are expressed by names based on a private language comprehensible only to field designers in many cases.

The drawing data 401 in the lowest hierarchy contains the following associated information: drawing vector information representing the external shape of the drawing data, a step label attached to each semiconductor manufacturing step in which the pattern of the drawing data is formed, and positional information on the drawing data 401. The step label is information representing which step in the semiconductor device manufacturing procedure the sample has passed, and design information on the uppermost layer of the wafer can be specified by specifying a step label.

The positional information on drawing data is expressed by positional information relative to the position of the origin of (coordinate system representing information on position of) a higher-level constituent unit. The positional information is described in the form of vector information representing distance and direction. The positional information is given to the constituent unit corresponding to each hierarchy as well as to the drawing data 401 and given in the form of vector information based on the position of the origin of the higher-level constituent unit. Information on planar arrangement of the parts that form the hierarchies is therefore provided from the density information computing processor 122 that sequentially reads the hierarchies shown in FIG. 4(a) from the above. The information on the drawing vectors, the step labels, and the positions described above are stored as information associated with the layout information in the design data server 130 and read when the design information is read into the density information computing processor 122. It is noted that the drawing data are shared by another hierarchy in the hierarchy structure in some cases.

A method for automatically calculating the pattern density in a region under inspection will next be described with reference to FIG. 4(c). The operator first operates the GUI to specify a step label. In this process, the operator specifies a part label of a pattern that the operator does not desire to inspect, for example, the part label 406 representing a dummy pattern, on the GUI window. Information on the specified step label and part label is forwarded to the density information computing processor 122.

The density information computing processor 122 uses the layout information shown in FIG. 4(a) and the information on the step label and the part label forwarded from the console 119 to temporarily draw a layout pattern of the chip under inspection. In this process, a part label of a part that the operator does not desire to inspect is omitted in the pattern drawing.

After the pattern in the chip is drawn, the pattern density or an alternative index to the pattern density of the constituent unit in each of the hierarchies in the hierarchical structure shown in FIG. 4(a) is calculated. Since the pattern has been already drawn, the area occupied by the part corresponding to each of the hierarchies and the area occupied by a predetermined pattern formed in the part can be calculated. For example, since the area occupied by the region 426 and the area occupied by the entire memory cells present in the region 426 shown in FIG. 4(b) can be calculated, the pattern density of the region 426 can be calculated.

Calculation involved in the pattern drawing takes time. On the other hand, in the present embodiment, it is not necessary to calculate an exact pattern density in each region, but information on pattern density is only used as reference information for determining the pixel dimension by using which a part under inspection is inspected. It may therefore be unnecessary to actually carry out drawing, but the narrowest line width of the part may be used to calculate a certain alternate index associated with the pattern density. Alternatively, only a small-scale part may be drawn, and the pattern density thereof may be calculated. The calculated alternative indices or pattern densities are classified (ranked) into categories the number of which is approximately the same as or several times the number of selectable pixel dimensions and used as reference information when the pixel dimension is determined. In the following description, the pattern density rank is used as an alternative index to the pattern density. The pattern density rank is a value representing how many times the narrowest line width of a pattern used in (region corresponding) a certain part is larger than a reference line width (narrowest line width in overall design information). When the narrowest line width of the pattern is N times the reference line width, the pattern density rank is N. When adjacent drawing data or parts are the same (that is, in the same hierarchy) and the adjacent pattern density ranks are the same, the adjacent drawing data or parts merge with each other.

FIG. 4(c) shows calculated pattern density ranks based on the layout information shown in FIG. 4(a) and obtained in accordance with the calculation rule described above. Consider now a part 410 corresponding to the memory mat. The plurality of drawing data 401 shown in FIG. 4(a) merge with each other because they have the same pattern density rank, and a pattern density rank 414 of the memory mat region is one. A pattern density rank 414 of a part 411, which corresponds to the dummy pattern, is zero because the pattern density rank is not calculated. The pattern density rank of a part 412, which corresponds to the I/O region, is 4 and 8, which shows that the I/O region is formed of three different regions, and that the pattern density ranks of the three regions are 4, 8, and 8, respectively. Similarly, a pattern density rank 417 of a part 413, which corresponds to the logic region, is 2 and 3.

The density information computing processor 122 thus calculates information on the density in each of the regions that form the layout pattern in the chip. The calculated density information is stored as density information on a product type and manufacturing step basis in the secondary storage means provided in the density information computing processor 122 or the overall controller 118 (step 302).

A procedure of creating the inspection recipe will next be described with reference to FIG. 3(b). The overall controller 118 first reads a standard recipe created and stored in advance. At the same time, the wafer 6, which is an object to be inspected, is loaded into the inspection apparatus. The overall controller 118 starts reading the standard recipe and loading the wafer 106 in response to an instruction inputted by the operator through the console 119. The loaded wafer 106 is placed on the sample table 109.

The overall controller 118 then sets optical system conditions, such as the voltage applied to the electron source 101, the magnitude at which the objective lens 104 is energized, the voltage applied to the charging control electrode 105, and the current applied to the deflector 103, based on the read standard recipe, sets based on the image of the standard sample piece 121 alignment conditions under which the correction between the coordinates with reference to the alignment mark on the wafer 106 and the coordinates of the XY stage 107 of the inspection apparatus is made, sets inspection region information representing a region to be inspected on the wafer 106, and sets calibration conditions in which the coordinates where an image used to adjust the brightness of an image is captured and an initial gain of the detector 113 are registered.

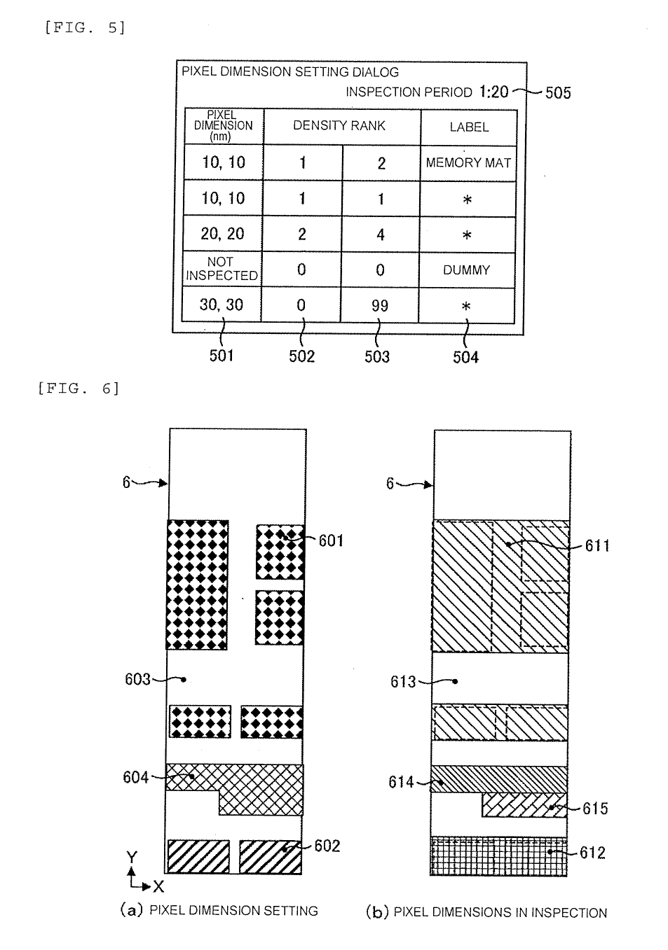

Thereafter, the inspection sensitivity is set (step 311), and the variable pixel dimension is set (step 312). To set the variable pixel dimension, a GUI dialog window shown in FIG. 5 is displayed. The dialog window shown in FIG. 5 is a setting window through which the pixel dimension and the pattern density rank of an inspection image assigned to each part label are specified. The reason why a plurality of pattern density ranks are assigned to parts having the same label is that, for example, memory cell patterns having different sizes are drawn in parts having the same memory mat name in some cases.

The GUI dialog window specifies the relationship among following items to be used in descending order of priority: pixel dimensions 501 in the X and Y directions; a start density rank 502 and an end density rank 503; and a part label 504. The pixel dimensions in the X and Y directions are not necessarily equal to each other, but they can be set independently in the X and Y directions. In the density rank fields, the start and end density ranks are specified, and the part label are specified by using a wildcard. Consider now that the region occupied by the density part 410 having density ranks specified by the start density rank 502 and the end density rank 503 and having a part label that agrees with that specified in the part label 504 is inspected by using the specified pixel dimensions 501. After the items described above are set, a method that will be described later in detail is used to simulate the inspection, and an expected inspection period 505 is displayed on the dialog.

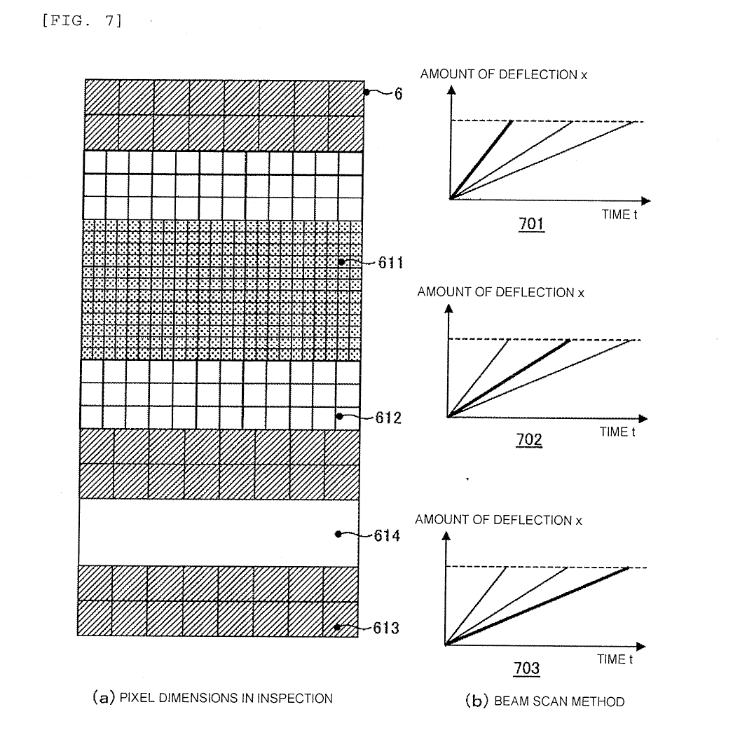

A method for setting the pixel dimension by using which actual inspection is performed will be described with reference to FIG. 6. FIG. 6 shows a state in which a scan stripe is so displayed that it is superimposed on the die layout of a die under inspection. FIG. 6(a) schematically shows the scan stripe displayed on the pixel dimension setting window, and FIG. 6(b) schematically shows the scan stripe set on an actual object to be inspected after the pixel dimensions are set in FIG. 6(a). The term “scan stripe” (hereinafter abbreviated to stripe) is the beam trajectory formed by continuously moving the sample stage and scanning the charged particle beam in a direction that intersects the direction in which the stage moves, and the resultant image has a band-like elongated shape. The direction in which the stage moves may be the Y direction or the X direction.

FIGS. 6(a) and 6(b) are enlarged views of the die layouts of part of the die. The width of the scan stripe is automatically set by the overall controller 118 based on the information (such as scan speed and sampling clock) specified in the “general inspection conditions” described with reference to FIG. 3(b). The stripe shown in FIG. 6(a) is in some cases displayed on the GUI window along with the dialog window shown in FIG. 5. As described with reference to FIG. 4, the inspection apparatus has already known information on the density in each region of the sample under inspection, and the relationship between the density information and the pixel dimensions used in the inspection has been already set on the dialog window shown in FIG. 5. The stripe displayed on the window shown in FIG. 6(a) therefore has regions segmented in accordance with the density ranks (or other pieces of density information).

Consider a case where the stripe is segmented as follows: a 10 nm-pixel specified region 601 where it is specified to perform inspection by using pixel dimensions of (10, 10 nm); a 20 nm-pixel specified region 602 where it is specified to perform inspection by using pixel dimensions of (20, 20 nm); a 30 nm-pixel specified region 603 where it is specified to perform inspection by using pixel dimensions of (30, 30 nm); and a non-inspection specified region 604 where it is specified to perform no inspection. It is assumed that the same pixel dimension is employed along a line along which the beam is scanned in the X-direction, and that the pixel dimension is changed when the line is switched to another. It is further assumed that the inspection is performed by using the smallest pixel dimension among those specified in the X direction.

FIG. 6(b) shows assignment of the pixel dimensions set on an actual sample under inspection based on the setting described above. The assignment is specifically made as follows: A region containing the 10 nm-pixel inspection region 601 corresponds to a 10 nm-pixel inspection region 611 where an image is acquired by using 10-nm pixels; a region containing the 20 nm-pixel inspection region 602 corresponds to a 20 nm-pixel inspection region 612 where an image is acquired by using 20-nm pixels; a region containing the 30 nm-pixel inspection region 603 corresponds to a 30 nm-pixel inspection region 613 where an image is acquired by using 30-nm pixels; and a region containing none of the pixel inspection regions described above corresponds to a no image acquisition region 614. A region which contains the no inspection specified region 604, where no inspection is performed, and where an image is acquired corresponds to an inspection mask region 615, where an image is acquired but no defect identification is made.

The operator is notified of the specified pixel dimensions and the specified regions to be inspected by using the pixel dimensions displayed in the form of map. At the same time, an expected inspection period required when the inspection is performed by using the pixel dimensions is displayed. When there is no problem with the results described above, the variable pixel dimension setting is completed. When there is a problem with the results, the dialog shown in FIG. 5 is displayed for modification.

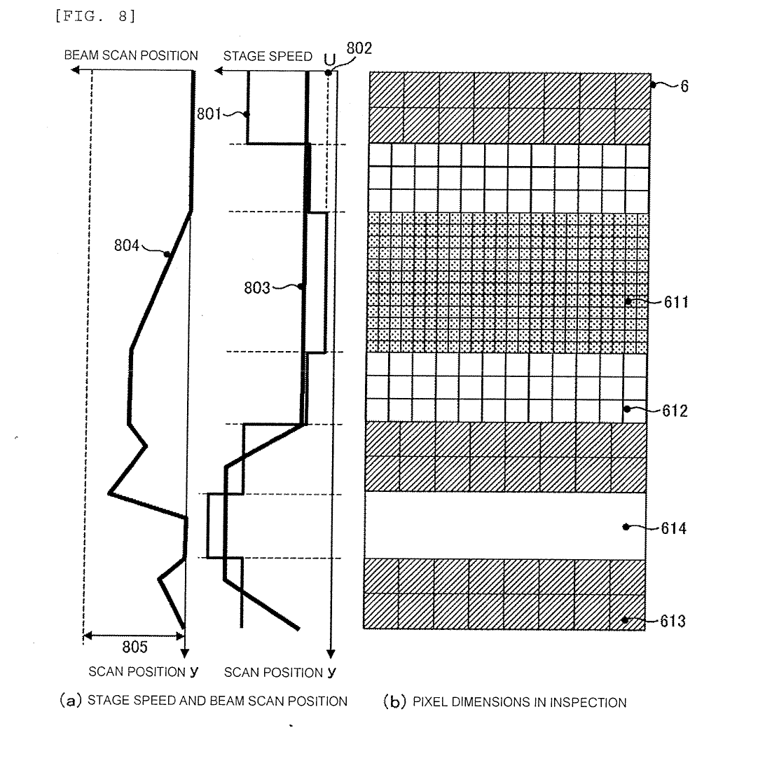

An instruction to scan the beam in accordance with the inspection pixel dimension setting will next be described with reference to FIG. 7. FIG. 7(a) is a schematic view showing the scan stripe 6 in which the 10 nm-pixel inspection region 611, the 20 nm-pixel inspection region 612, the 30 nm-pixel inspection region 613, and the no image acquisition region 614 are arranged. FIG. 7(b) is a comparison diagram showing the relationship of the amount of deflection of the beam scanned in the X direction versus time in the region inspected by using each of the pixel sizes. The thick solid lines represent the change in the amount of beam deflection versus time for the respective pixel dimensions. When the pixel dimension is small (in 10 nm-pixel inspection region 611), an image having a specified width is acquired by slowly scanning the beam. Now, let V be the beam speed and L be the number of pixels acquired in the image having the specified width. In 20 nm-pixel beam scanning 702, the beam is scanned at a speed 2V, which is twice faster than the beam scan speed described above, and an image formed of L/2 pixels is acquired. Since the pixel dimension is doubled, one-half the pixels provide the same image width. Similarly, in 30 nm-pixel beam scanning 703, the beam is scanned at a speed 3V, which is three times faster than the beam scan speed described above, and an image formed of L/3 pixels is acquired.

An instruction to scan the stage in accordance with the inspection pixel dimension setting will next be described with reference to FIG. 8. FIG. 8(b) is a schematic view of the scan stripe in which the inspection pixels having the same dimensions as those specified in FIG. 7(a) are arranged, and FIG. 8(a) shows a temporal change in a stage drive control signal for acquiring an image by using the inspection pixel dimensions specified in FIG. 8(a) and a temporal change in the amount of beam deflection in the Y direction that corresponds to the stage drive operation. In the diagram showing the temporal change in the amount of beam deflection in the Y direction shown in FIG. 8(a), the horizontal axis represents time, and the vertical axis represents the amount of beam deflection in the Y direction (beam irradiation position). In FIG. 8, reference numeral 805 denotes the maximum amount of beam deflection in the Y direction, which is equal to the FOV size. The stage speed cannot be abruptly changed due to physical restrictions, and the stage needs to be driven at certain acceleration or lower. On the other hand, an ideal stage moving speed 801 is ideally set as follows: Assuming that the stage is moved at a stage speed U (802) in the 10 nm-pixel inspection region 611, the stage speed in the 20 nm-pixel inspection region 612 is 4 U, which is increased in proportion to the square of the pixel dimension, and the stage speed in the 30 nm-pixel inspection region 613 is 9 U from the same reason. Since the stage can only be driven at a certain acceleration or lower, consider that the stage is driven at an actual stage speed 803. The difference between the ideal stage speed 801 and the actual stage speed 803 is compensated by controlling the beam position. That is, the beam is scanned based on the amount of beam delay in the Y direction (positive or negative amount of beam deflection in Y direction from reference point synchronized with ideal stage speed). When the actual stage speed 803 is higher than the ideal stage speed 801, the beam cannot be scanned with the beam position fixed but the beam is scanned by increasing the amount of beam delay 804. When the actual stage speed 803 is lower than the ideal stage speed 801, the amount of delay 804 is reduced. Images can be acquired without any problem as long as the maximum amount of delay falls within the FOV (field of view) of the electronic optical system. The overall controller 118 computes in advance the highest actual stage speed 803 within the condition in which the amount of delay satisfies the FOV condition and displays the expected inspection period 505 shown in FIG. 5.

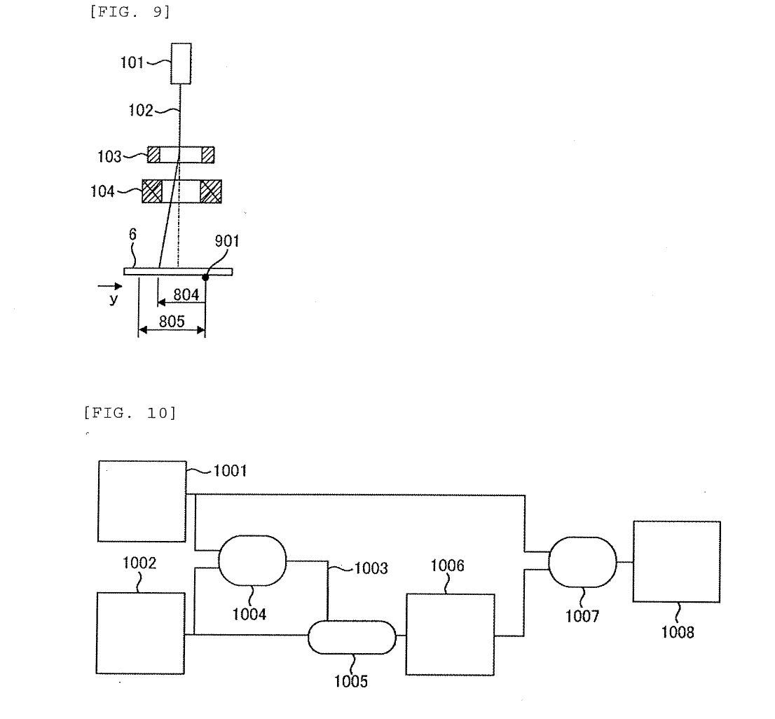

The amount of beam scan delay 804 will be described in detail with reference to FIG. 9. FIG. 9 is a descriptive diagram showing the relationship between necessary parts in the electronic optical system and the field of view resulting from beam deflection. The primary charged particle beam 102 emitted from the electron source 101 travels along the beam deflector 103, which controls the amount of beam delay 805 corresponding to the beam irradiation position on the wafer 6, and the objective lens 104, which narrows the beam diameter on the wafer 6, and irradiates the wafer 6. The field of view is so sized that an effective image restricted by the performance of the objective lens 104 and other components can be acquired. An FOV origin 901, which is a point on the edge of the field of view on the wafer 6, is set, and the amount of beam delay 804 is defined as the amount of delay from the FOV origin 901. An image can be acquired as long as the amount of delay falls within the range from the FOV origin 901 to the FOV (field of view) 805.

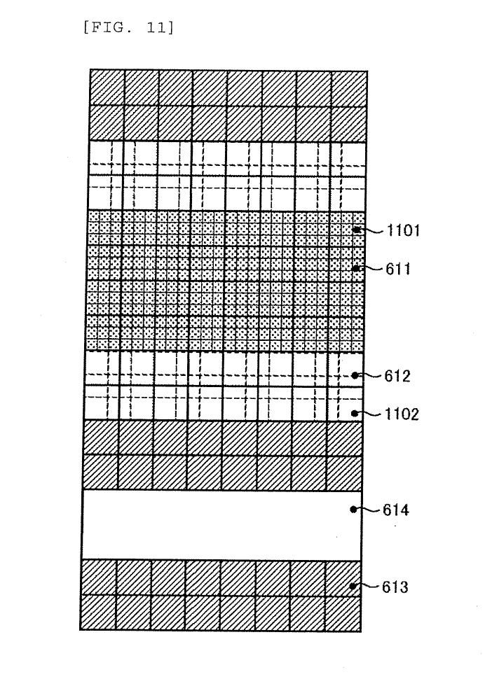

The variable pixel dimensions are set by using the means described above, and then an image is acquired under the thus set conditions. The acquired image has different pixel dimensions depending on which region the pixels belongs to: the 10 nm-pixel inspection region 611; the 20 nm-pixel inspection region 612; and the 30 nm-pixel inspection region 613, which have been set as described above. Processes carried out by the defect identification unit 117 will be described with reference to FIG. 10. The defect identification is performed as follows: an alignment section 1004 determines the amount of shift 1003 between a detected image 1001 in which detected pixel dimensions differ among the regions and a reference image 1002 acquired in advance; an image shifting section 1005 produces an aligned reference image 1006 obtained by shifting the reference image 1002 in accordance with the amount of shift 1003; and a difference image extracting section 1007 computes a difference image 1008 between the detected image 1001 and the aligned reference image 1006. Defect information 116, such as the coordinates and characteristic values of the defects, is computed based on the difference image 1008.

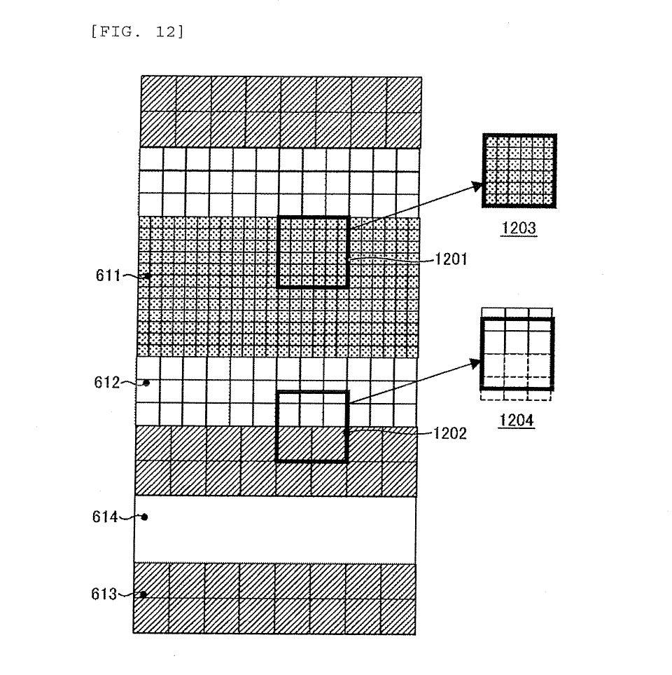

The operation of the alignment section 1004 will be described with reference to FIG. 11. Alignment needs to be performed with the pixel dimensions equally sized. FIG. 11 describes a resampling method for equally sizing the pixel dimensions. The 10 nm-pixel inspection region 611 produces a resampled image 1101 having 30-nm pixels, and the 20 nm-pixel inspection region 612 produces a resampled image 1102 having 30-nm pixels. In general, image resampling is performed by thinning an image by using low-frequency-pass filtering that leaves only significant frequency components in a resampled pixel dimension. The resampling, which eliminates low frequency components, extracts memory mat contours, large peripheral circuit pattern contours, and any other unique pattern with no pattern similar thereto around the pattern in the resampled image, and the alignment is performed based on the extracted patterns. The alignment method used in the present embodiment is the same as that used in related art, and no detailed description of the alignment method will therefore be made.

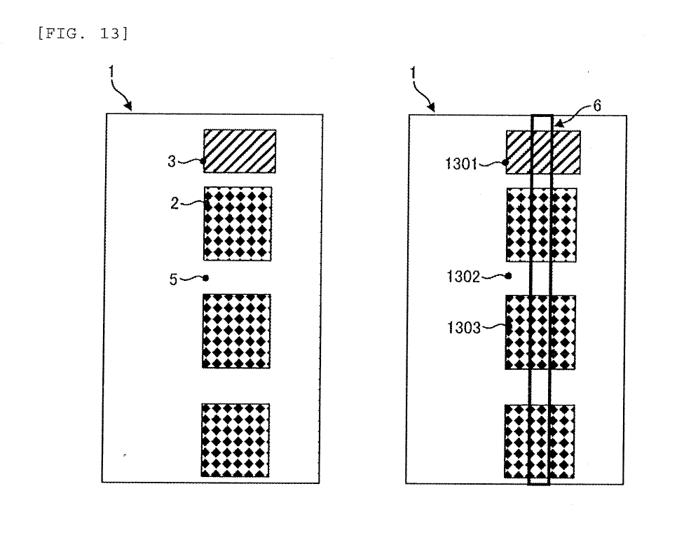

On the other hand, the resampling operation in the difference computation performed by the difference image extracting section 1007 will be described with reference to FIG. 12. The detected image 1001 and the aligned reference image 1006 are divided into small regions of about 256 by 256 pixels, and the difference is computed for each of the divided regions. Consider now two divided regions 1201 and 1202. Resampled images 1203 and 1204 having the minimum pixel dimension are produced in correspondence with the two regions, and difference images are extracted based on the resampled images 1203 and 1204. In the process of extracting the difference images, the inspection mask region 615 masks the difference images. A method for extracting a difference image used in the present embodiment is the same as that used in related art, and no detailed description of the method will therefore be made.

A trial inspection using the thus set variable pixel dimensions is performed (step 313 in FIG. 3), and inspection condition checking in which inspection results are checked (step 314) is performed. When the inspection conditions are inappropriate, the sensitivity condition setting (step 311) and the variable pixel dimension setting (step 312) are made again, and the trial inspection (step 313) and the inspection condition checking (step 314) are performed. In this way, appropriate inspection conditions are set and stored in the form of recipe, and the wafer 106 is unloaded. The recipe creation is thus completed.

FIG. 3(c) shows the inspection procedure. The recipe stored in FIG. 3(b) is read, and the wafer 106 to be inspected is loaded into the inspection apparatus. According to the specifications of the wafer 106, the operator uses the console 119 to select or specify the stripe-shaped inspection region to be actually inspected, the pixel dimensions, the number of line summation, and other parameters so that the optical system conditions are set in the overall controller 118; align the coordinates of the semiconductor wafer 106 with those of the XY stage 107; and perform calibration for adjustment of the brightness of an image. The defect inspection then starts, and the following series of processes are repeated until the inspection of a predetermine die is completed: defect identification performed by acquiring images of a specified inspection region, comparing the images with each other to extract the difference therebetween, and setting the difference as a defect candidate; and storing representative coordinates of the difference image, the compared images, and the defect candidate in a storage device (not shown). After the last die set on the wafer 106 is inspected, the wafer 106 is unloaded.

The present embodiment, in which the pixel dimension used in inspection is changed based on design information, is characterized in that the inspection conditions can be set in substantially the same manner as in inspection of related art.

Further, the present embodiment, in which a region that is not desired to be inspected, such as a dummy pattern, is set not to be inspected based on design information, is characterized in that only essential defects can be extracted.

Further, the present embodiment, in which the amount of beam delay in the direction in which the stage is driven is controlled, is characterized in that an image can be acquired even when the stage is driven differently from an ideal drive operation.

Further, the present embodiment, in which the stage drive speed is variable and the amount of beam delay is controlled, is characterized in that inspection can be so performed that the difference in the inspection period between the ideal stage speed and the actual stage speed is small.

As described above, the invention can provide a high-speed inspection method and apparatus having appropriate sensitivity according to the pattern density and pattern characteristic of a device.

### Second Embodiment

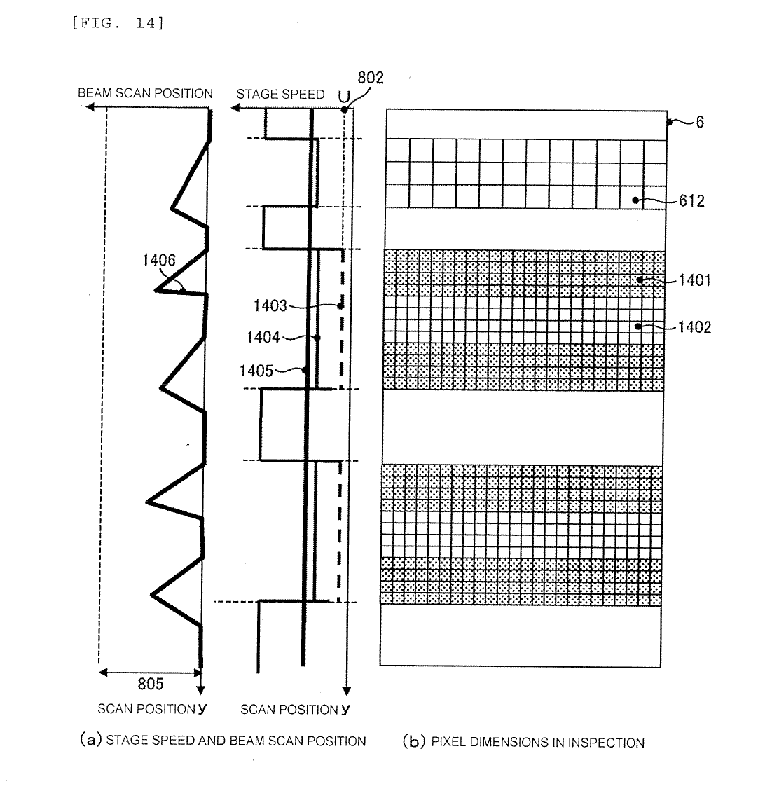

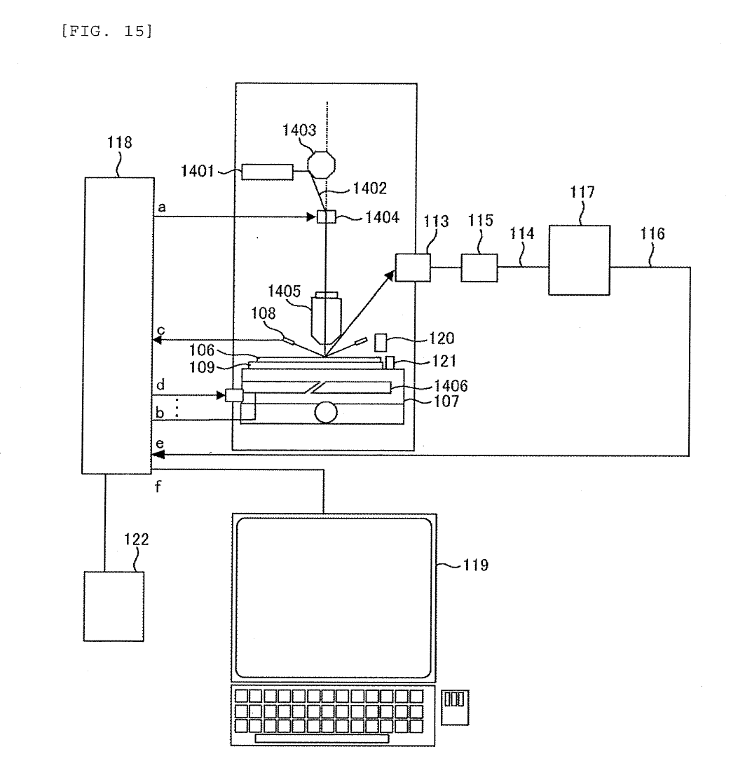

A second embodiment of the invention will be described with reference to FIGS. 13 and 14. The configuration of an apparatus according to the second embodiment is the same as that of the apparatus according to the first embodiment and only differs therefrom, for example, in terms of the stage drive method, and only different portions will therefore be described.

FIG. 13 describes an example of the layout on a device to be inspected in the second embodiment. FIG. 13(a), a left portion of FIG. 13, is a schematic view showing the layout on an actual object under inspection, and FIG. 13(b), a right portion of FIG. 13, is a schematic view showing a stripe disposed on the object under inspection. A die 1 is formed of a high-density region 2, a middle-density region 3, and a region not to be inspected 5. Consider now that the portion corresponding to a stripe 6 is inspected, that is, a case where the high-density region 2 occupies a large part of the stripe 6 and the middle-density region 3 and other regions occupy a small part of the stripe 6. It is assumed that the middle-density region undergoes entire image acquisition 1301, the region not to be inspected undergoes no image acquisition 1302, and the high-density region undergoes sampled image acquisition 1303.

A sampled image acquisition method and a stage drive method will be described with reference to FIG. 14. In the high-density region 2, an image acquisition region 1401 and a no image acquisition region 1402, each of which is formed of a fixed number of lines (128 or 256 lines, for example), are alternately arranged. The sampling is not necessarily performed at equal intervals, and an image of the high-density region is so acquired that the sum of the image acquisition regions 1401 accounts for a fixed percentage of the entire region (25%, for example, 66% in FIG. 13).

Since no image is acquired in the no image acquisition regions 1402, the ideal stage speed increases in proportion to the reciprocal of the sampling rate, that is, changes from 1403 to 1404. As a result, when the actual stage speed is set at a fixed value 1405, the amount of beam delay 1406 is reduced to fall within the FOV 805 or lower, whereby an image can be acquired.

According to the present embodiment, the inspection can be performed at higher speed by performing sampling inspection in the high-density region.

According to the present embodiment, since the stage is driven at a fixed speed, it is not necessary to suppress vibration resulting from acceleration and deceleration, whereby the cost of the configuration of the apparatus decreases.

A first variation of the present embodiment will be described. The first variation has a multi-beam configuration in which a plurality of charged particle beams are used. According to the present variation, a significantly high-speed system can be configured based on an increase in speed according to the increase in the number of beams and the variable pixel size technology including the sampling.

A second variation of the present embodiment will be described. The defect identification method is not limited to the method for comparing a detected image with a reference image and can be a cell comparison method in which a repetitive pattern is assumed, a golden pattern comparison method in which a detected image is compared with a golden pattern acquired in advance, and other suitable methods. The present variation, in which the cell comparison method capable of identifying a defect with high sensitivity is combined with the golden pattern inspection method, is characterized in that the defect identification can be more sensitive.

### Third Embodiment

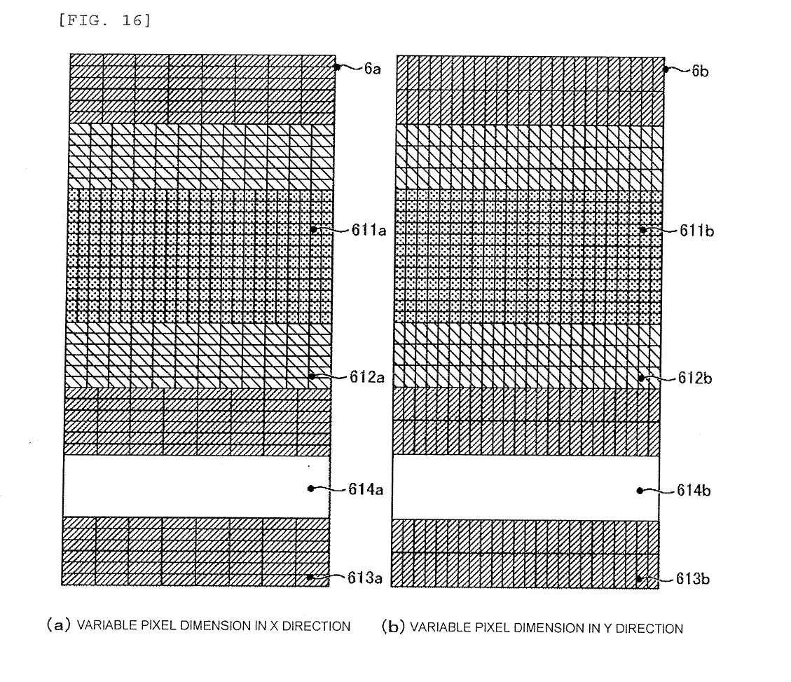

A third embodiment will next be described with reference to FIG. 15. FIG. 15 shows the configuration of an apparatus according to the third embodiment, which is an example of an optical inspection apparatus. A laser light source 1401 emits laser light 1402 (corresponding to primary charged particle beam 102), which is scanned by a polygonal mirror 1403 (corresponding to X-direction scanning performed by deflector 103), and the amount of scan delay in the Y direction (corresponding to Y-direction scanning performed by deflector 103) is adjusted by a galvanometric mirror 1404. The laser light 1402 then irradiates a wafer 106 via an objective lens 1405. The resultant scattered light is detected by a detector (sensor) 113. The energizing adjustment made on the objective lens is replaced with a Z stage 1406 driven, for example, by a piezoelectric device. The same operation as that in the first or second embodiment is achieved by replacing the operation of the corresponding portions. The present embodiment is characterized in that high-speed inspection is achieved by an optical inspection apparatus.

### Fourth Embodiment

In the present embodiment, a description will be made of an inspection method in which the shape of each pixel is not square but is rectangular. The overall configuration and operation of an apparatus according to the present embodiment are substantially the same as those shown in the first embodiment, and redundant description will therefore be omitted and FIG. 2 is referred to as appropriate.

FIG. 16(a) shows a variation of the beam scanning method shown in FIG. 7(a) (first embodiment) that differs therefrom in that the pixel dimension is changed only in the X direction. In other words, the variation is an inspection method in which only the pixel dimension in the beam scanning direction is changed while the pixel dimension in the stage scanning direction is maintained at the minimum pixel dimension (10-nm pixel). The pixel dimensions in inspection regions set in a stripe are as follows: An inspection region 611a is a 10 nm-pixel inspection region; a region 612a is a 20 nm-pixel inspection region; and a region 613a is a 30 nm-pixel inspection region.

The beam scanning is so controlled that the beam is slowly scanned when the pixel dimension is small (in 10-nm pixel inspection region 611a) to acquire an image of a specified width, as in the method shown in FIG. 7(b). In this case, let V be the beam speed and L be the number of pixels acquired in the image having the specified width. In the 20-nm pixel beam scanning 702, the beam is scanned at the speed 2V, which is twice faster than the beam scan speed described above, and an image formed of L/2 pixels is acquired. Since the pixel dimension is doubled, one-half the pixels provide the same image width. Similarly, in the 30 nm-pixel beam scanning 703, the beam is scanned at the speed 3V, which is three times faster than the beam scan speed described above, and an image formed of L/3 pixels is acquired.

When the beam scan speed is changed, the period required to scan the beam across a single line changes and the stage speed synchronized with the beam scanning also changes. It is therefore necessary to change the stage scan speed. To this end, the stage scan speed is changed in correspondence with the beam scan speed. The stage scan control can be performed in a manner similar to the method shown in FIG. 8, and portions where only numerical values are changed will therefore be described below. Assuming that the ideal stage moving speed 801 is U (802) in a 10-nm pixel inspection region 611a, the stage speed in a 20-nm pixel inspection region 612a is 2 U, which is increased in proportion to the pixel dimension, and the stage speed in a 30-nm inspection region 613a is 3 U from the same reason. That is, the stage moving speed in the inspection region using the minimum pixel dimension is used as a unit speed, and the ratio of a target pixel dimension to the minimum pixel dimension is used as a coefficient. The unit speed multiplied by the coefficient may then be used as the stage moving speed for the target pixel dimension. The other control operation is the same as that shown in FIG. 8. The beam scan control and the stage drive control described above are performed by the overall controller 118.

FIG. 16(b) shows the arrangement of inspection regions using respective pixel dimensions in a stripe in a case where the pixel dimensions are changed only in the Y direction oppositely to FIG. 16(a), that is, in a case where the inspection pixel dimension in the stage scan direction is variable while the pixel dimension in the beam scan direction is maintained at the dimension of the 10-nm pixel, which is the minimum pixel dimension. The pixel dimensions in the inspection regions set in the stripe are as follows: An inspection region 611b is the 10-nm pixel inspection region; a region 612b is the 20-nm pixel inspection region; and a region 613b is the 30-nm pixel inspection region.

In the case shown in FIG. 16(b), since the pixel dimensions are the same in the beam scan direction, no control according to the pixel dimension in the beam scan direction is necessary, unlike the case shown in FIG. 16(a). On the other hand, the stage scan speed needs to be controlled in accordance with the pixel dimensions. As in the case shown in FIG. 16(a), the stage moving speed in the inspection region using the minimum pixel dimension is used as a unit speed, and the ratio of a target pixel dimension to the minimum pixel dimension is used as a coefficient. The stage is then so controlled that the unit speed multiplied by the coefficient is set to be the stage moving speed for the target pixel dimension. Specifically, assuming that the ideal stage moving speed 801 is U (802) in the 10-nm pixel inspection region 611b, the stage speed in the 20-nm pixel inspection region 612b is 2 U, which is increased in proportion to the pixel dimension, and the stage speed in the 30-nm inspection area 613b is 3 U from the same reason. The other control operation is the same as that shown in FIG. 8. The stage scan control described above is performed by the overall controller 118.

The configuration of the present embodiment, in which the control in the stage scan direction and the beam scan direction is simplified, is characterized in that an inspection apparatus having a less expensive configuration can be provided.

Although no description will be made in detail, instead of fixing the pixel dimensions in the beam scan direction or the stage scan direction, the pixel dimensions in the beam scan direction and the stage scan direction can alternatively be so set that they differ from each other. The present variation, in which the degree of freedom in setting the pixel dimensions increases, is characterized in that more flexible inspection can be performed. Similarly, the pixel dimensions have been described with reference to the case where integral multiples of the unit pixel dimension are used, but arbitrary pixel dimensions, such as 10 nm, 11 nm, and 12 nm, can be set under the restriction in which the width in the beam scan direction is substantially maintained at a single value. The present variation, in which the pixel dimension is changed by a small increment, is characterized in that a more suitable tradeoff relationship between the defect inspection sensitivity and the inspection speed can be set. Further, in FIGS. 16(a) and 16(b), a method for controlling the beam scan speed and the stage scan speed with reference to the minimum pixel dimension has been described. Alternatively, the pixel size in either of the X and Y directions is fixed at the maximum pixel dimension or any other arbitrary dimension, and the pixel dimension in the other direction can be changed.

### REFERENCE SIGNS LIST

1 Die

2 High-density region

3 Middle-density region

4 Low-density region

5 Region not to be inspected

6 Scan stripe

7 Stage movement

8 Minute-pixel image acquisition

9 Small-pixel image acquisition

10 large-pixel image acquisition

101 Electron source

102 Primary charged particle beam

103 Deflector

104 Objective lens

105 Charging control electrode

106 Wafer

107 XY stage

108 Z sensor

109 Sample table

110 Secondary charged particle

111 Reflector

112 Secondary signal defector

113 Detector

114 Digital signal

115 A/D converter

116 Defect information

117 Defect identification unit

118 Overall controller

119 Console

120 Optical microscope

121 Standard sample piece

122 Density information computing processor

130 Design data server

301 Density information conversion step

311 Inspection sensitivity setting step

312 Variable pixel dimension setting step

313 Trial inspection step

314 Inspection condition checking step

401 Drawing data

402, 403 Part

404 Design information

405 Part label (memory mat)

406 Part label (dummy)

407 Part label (I/O)

408 Part label (logic)

410 Part (memory mat)

411 Part (dummy)

412 Part (I/O)

413 Part (logic)

414, 415, 416, 417 Pattern density rank

420 Chip

421 Memory region

422 Logic region

423 I/O region

424 Memory mat

425 Memory cell

426 Region

501 Pixel dimension

502 Start density rank

503 End density rank

504 Part label

505 Expected inspection period

601 10-nm pixel specified region

602 20-nm pixel specified region

603 30-nm pixel specified region

604 No inspection specified region

611 10-nm pixel inspection region

612 20-nm pixel inspection region

613 30-nm pixel inspection region

614 no image acquisition region

615 Inspection mask region

701 10-nm pixel beam scanning

702 20-nm pixel beam scanning

703 30-nm pixel beam scanning

801 Ideal stage moving speed

802 Stage speed U

803, 1405 Actual stage speed

804, 1406 Amount of beam delay

805 FOV

901 Origin of field of view

1001 Detected image

1002 Reference image

1003 Amount of shift

1004 Alignment section

1005 Image shifting section

1006 Aligned reference image

1007 Difference image extracting section

1008 Difference image

1101 Resampled image (30 nm)

1102 Resampled image (20 nm)

1201 10-nm pixel region

1202 20 nm/30 nm pixel mixed region

1203 10-nm image

1204 20-nm resampled image

1301 Entire image acquisition

1302 No image acquisition

1303 Sampled image acquisition

1401 Laser light source

1402 Laser light

1403 Polygonal mirror

1404 Galvanometric mirror

1405 Objective lens

1406 Z stage

1. A circuit pattern inspection apparatus that detects secondary electrons or reflected, back scattered electrons produced when a primary charged particle beam irradiates a sample substrate on which a circuit pattern is formed and uses an image produced from the detected secondary electrons or reflected electrons to determine whether or not a defect is present on the sample substrate, the circuit pattern inspection apparatus comprising:
a sample stage on which the sample substrate is placed and which moves the sample substrate in a predetermined direction;
a charged particle column having a function of scanning the primary charged particle beam over the sample substrate in a direction that intersects the direction in which the sample stage moves, detecting the secondary electrons or the reflected electrons, and outputting the detected electrons as a secondary particle signal; and
control means for controlling the charged particle column and the sample stage, and
inspection is performed with a pixel dimension changed in accordance with the position on the sample substrate by acquiring the image with the pixel dimension changed in a single sequence of the inspection of the sample substrate.

2. The circuit pattern inspection apparatus according to claim 1, wherein
the pixel dimension is changed in a scan stripe formed by scanning the primary charged particle beam and moving the sample stage.

3. The circuit pattern inspection apparatus according to claim 2, wherein
the pixel dimension is changed by changing the speed at which the primary charged particle beam is scanned.

4. The circuit pattern inspection apparatus according to claim 2, wherein
the pixel dimension is changed by changing the speed at which the sample stage is moved.

5. The circuit pattern inspection apparatus according to claim 1, wherein
the circuit pattern inspection apparatus further comprises a console screen on which a setting window for setting a pixel dimension according to the position on the sample substrate is displayed, and
the console screen displays information on the layout of the circuit pattern and information on circuit pattern density in each region of the layout.

6. The circuit pattern inspection apparatus according to claim 1, wherein
the circuit pattern inspection apparatus further comprises a console screen on which a setting window for setting a pixel dimension according to the position on the sample substrate is displayed, and
an image of part of the circuit pattern on the sample substrate is acquired in advance, and the console screen displays information on circuit pattern density in each region of the circuit pattern that is estimated from the acquired image.

7. The circuit pattern inspection apparatus according to claim 1, wherein
the circuit pattern inspection apparatus further comprises:
image formation means for forming a secondary particle image from the secondary particle signal; and
comparison computation means for comparing the secondary particle image with a reference image to determine whether or not a defect is present, and
the comparison computation means resamples the secondary particle image and the reference image to adjust the pixel dimensions thereof.

8. The circuit pattern inspection apparatus according to claim 7, wherein
the comparison computation means performs first resampling on the secondary particle image and the reference image to equally sizing the pixel dimensions thereof.

9. The circuit pattern inspection apparatus according to claim 7, wherein
the comparison computation means performs second resampling on the secondary particle image and the reference image to equally sizing the pixel dimensions thereof on a comparison unit basis.

10. The circuit pattern inspection apparatus according to claim 9, wherein
the comparison computation means
performs the second resampling on the secondary particle image and the reference image having undergone an alignment to equalize the pixel dimensions thereof on a comparison computation unit basis, and
uses the secondary particle image and the reference image having undergone the second resampling to perform the comparison computation.

11. The circuit pattern inspection apparatus according to claim 10, wherein
the comparison computation means
performs first resampling for equally sizing the pixel dimensions on the secondary particle image and the reference image on which the second resampling is performed and uses the secondary particle image and the reference image having undergone the first resampling to align the secondary particle image and the reference image with each other.

12. The circuit pattern inspection apparatus according to claim 1, wherein
the circuit pattern inspection apparatus further comprises comparison computation means for comparing the secondary particle image with a reference image to determine whether or not a defect is present,
the circuit pattern inspection apparatus can set a region not to be inspected where no inspection is performed on the pattern layout of the circuit pattern formed on the sample substrate, and
the comparison computation is not performed on the region not to be inspected.

13. A circuit pattern inspection apparatus that detects reflected light produced when light irradiates a sample substrate on which a circuit pattern is formed, the circuit pattern inspection apparatus comprising:
a sample stage on which the sample substrate is placed and which moves the sample substrate in a predetermined direction; and
imaging means having a function of scanning the light over the sample substrate in a direction that intersects the direction in which the sample stage moves, focusing the reflected light, and outputting the focused light as an image signal, and
inspection is carried out with a pixel dimension changed in accordance with the position on the sample substrate by acquiring image signals produced based on different pixel dimensions in a scan stripe formed by scanning the light and moving the sample stage.
